(19) United States
(12) Patent Application Publication
(10) Pub. No.: US 2022/0416691 A1
(43) Pub. Date: Dec. 29, 2022

(54) ENERGY HARVESTING APPARATUS HAVING PIEZOELECTRIC ARMS

(71) Applicant: QPOWER LTD, Rosh Haayin (IL)

(72) Inventors: SHIMON PODVAL, RISHON LEZION (IL); GABRIEL SEIDEN, REHOVOT (IL); LIOR BLANKA, ROSH HAAYIN (IL)

(21) Appl. No.: 17/590,886

(22) Filed: Feb. 2, 2022

Related U.S. Application Data
(63) Continuation-in-part of application No. 17/361,444, filed on Jun. 29, 2021.

(51) Int. Cl. H02N 2/18; H01L 41/113

(52) U.S. Cl. CPC H02N 2/186; H01L 41/1134

(57) ABSTRACT

A device for harvesting motion energy, the device having an outer structure, multiple piezoelectric units having a permanent source of electromagnetic field (magnet or electret) attached to a piezoelectric material, where each of the piezoelectric units is fixed, at least in part, to the outer structure, where the inner structure is configured to be free to move within the outer structure, and an electric circuit configured to store or provide electric energy supplied by the piezoelectric units due to strain caused by relative motion between the outer structure and the inner structure.

### FIELD

The invention generally relates to harvesting energy, more specifically to harvesting energy by a device having piezoelectric arms.

### BACKGROUND

Energy harvesting systems convert ambient energy sources into accessible, stored energy in order to power electronic devices. Ambient energy sources may include solar energy, wind energy, thermal energy, kinetic (motion) energy and the like.

There is a growing interest in energy harvesting devices designed to power small, autonomous devices, such as wearable electronics, sensors, end-devices and the like. These wearable devices are typically powered by body motion, which has a characteristic frequency on the order of 1 Hz.

A prominent energy harvesting technology utilized for such wearable devices is based on piezoelectric energy harvesters (PZEH). Ideally, the resonance frequency of the harvester should match the characteristic frequency of the ambient motion in order to be efficient. In order to fulfill this requirement, current PZEH devices use a frequency-matching agent (also termed frequency-up-converter due to the relatively high resonance frequency of PZEH), such as multiple harvesting units (e.g., piezoelectric cantilevers) having varying natural frequencies. The need for frequency-matching agents usually results in a more complicated and expensive device. For example, in case of a device having multiple harvesting piezoelectric resonators, the resultant PZEH is larger and more expensive to produce due to the incorporation of the frequency-matching agent.

Yet another challenge in PZEH design relates to the fact that unlike ambient sources where there is a predetermined, well-defined orientation, in which the harvesting device needs to be aligned in order to have optimal performance, wearable devices may have arbitrary, spatially-dependent motion.

There is therefore a need to provide a PZEH-based method, system and device that is energy efficient, cost effective and spatially isotropic.

### SUMMARY

The invention, in an embodiment thereof, provides a PZEH device designed to harvest motion energy. The device includes an outer structure, a plurality of piezoelectric harvesting units, and an inner structure. The inner structure is movable inside the outer structure and is not attached to any of the piezoelectric harvesting units or to the outer structure. The inner structure's shape may be a cube like shape, ball-like shape, a spheroid, an ellipsoid, paraboloid, hyperboloid, or a shape resembling them. The electric circuit may include a battery, charging battery, a super capacitor and the like. The electric circuit may include power management circuits or any other electrical components or circuits in a way that enables the usage of the harvested energy for powering electrical circuits or enables to store the harvested electric energy or to use the harvested energy for charging batteries or other energy storage entities.

The piezoelectric harvesting units are fixed to the outer structure walls.

Under no ambient motion the inner structure may be rest on a bottom piezoelectric harvesting units due to gravity forces. When ambient motion occurs, the outer structure moves in accordance with the ambient motion. However, the free inner structure moves due to an inertia-induced fictitious force, which is proportional to both the mass of the inner structure and to the instantaneous acceleration pertaining to the ambient motion of the outer structure. The direction of the fictitious force is opposite to the direction of the instantaneous acceleration pertaining to the ambient motion.

The relative motion of the inner structure causes a collision between the inner structure and the piezoelectric harvesting units. The piezoelectric arms deform as a result of the dynamic mechanical interactions between the moving inner structure and the piezoelectric harvesting units. This deformation excites the natural frequencies of the piezoelectric units. The energy associated with the resonating piezoelectric harvesting units is then harvested by the electric circuit. The excitation of the natural frequencies associated with the piezoelectric harvesting units is independent of the characteristic ambient motion frequency as well as of the spatial orientation of the motion.

The invention, in an embodiment thereof, provides a device for harvesting motion energy, the device including an outer structure, a plurality of piezoelectric harvesting units where each of said piezoelectric units is fixed, at least in part, to said outer structure, an inner structure freely moving inside the outer structure, an electric circuit configured to store or provide electric energy supplied by said piezoelectric units due to strain caused by mechanical interaction between said outer structure and said inner structure.

In some cases, the piezoelectric units are in the form of cantilevers fixed at one end to the outer structure. In some cases, the device includes six piezoelectric harvesting units, where the outer structure includes at least three perpendicular walls.

In some cases, the electric circuit includes means to store the electric energy.

In some cases, the plurality of piezoelectric harvesting arms deforms in response to movement of the inner structure relative to the plurality of piezoelectric harvesting arms. In some cases, the inner structure is made of metallic material, from polymers, from synthetic materials, from organic materials and a combination thereof.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 shows a perspective view including the internal parts of the device for harvesting energy, according to exemplary embodiments of the invention;

FIG. 2 shows a perspective view of a single piezoelectric unit, according to exemplary embodiments of the invention; and

FIG. 3 shows a high level block diagram view of an energy harvesting circuit, according to exemplary embodiments of the invention.

### DETAILED DESCRIPTION

The following detailed description makes reference to the accompanying drawings, which form a part hereof. The illustrative description and specific examples of the embodiments are not meant to be limiting.

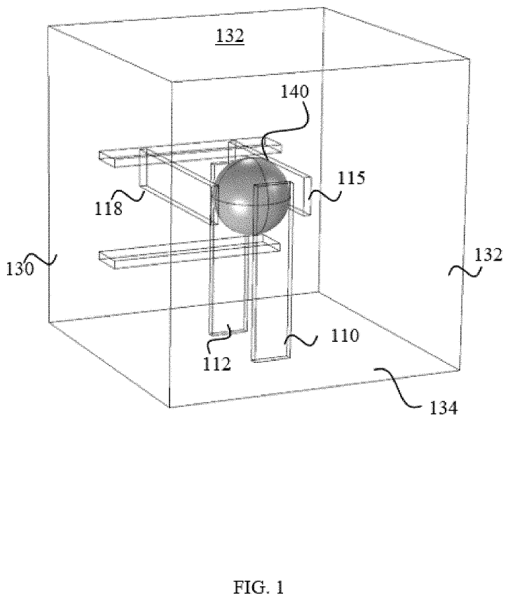

FIG. 1 shows a perspective view including the internal parts of the device for harvesting energy, according to exemplary embodiments of the invention.

The device comprising piezoelectric units 110, 112, 115, 118. The number of piezoelectric units included in the device may vary, and be selected by a person skilled in the art. FIG. 1 shows an exemplary embodiment, in which the device includes six (6) identical cantilever-shaped piezoelectric units. The device also includes a ball shaped inner structure and an outer structure.

The outer structure is defined by sidewalls having an internal surface and an external surface. The outer structure may be sealed, preventing liquid to flow and touch the inner structure. The outer structure may surround the entirety of the inner structure. The outer structure may include voids enabling passage of air into the volume defined between the walls of the outer structure. The outer structure may include an aperture enabling to insert a cable to collect the electric energy stored in the electrical circuit, in case the electrical circuit is located inside the outer structure.

The shape of the outer structure may be defined by walls 130, 132, 134 forming the outer structure. The walls 130, 132, 134 may be flat, defined as all regions in the wall point towards the same direction or azimuth. In some other cases, at least a portion of the walls may be elliptical. The external surface of the walls 130, 132, 134 of the outer structure may be accessible to a person, for example in order to secure the outer structure to another object.

The piezoelectric units 110, 112, 115, 118 are physically secured to the inner surface of the walls assembling the outer structure. For example, piezoelectric units 110 and 112 are secured to wall 134 and piezoelectric units 115 and 118 are secured to wall 130. Piezoelectric units 110, 112, 115, 118 may be secured to the walls assembling the outer structure using adhesive materials, by welding, or using any other technique selected by a person skilled in the art.

The device also includes an inner structure 140 located in its entirety inside the outer structure. The inner structure 140 is configured to be in minimal physical contact with the piezoelectric units 110, 112, 115, 118 when in resting position. The minimal physical contact may be defined by the surface area in which the inner structure 140 touches the piezoelectric units 110, 112, 115, 118. This way, the inner structure 140 may be of a ball-like shape, an ellipsoid, a paraboloid, a hyperboloid and the like. In some cases, the inner structure 140's shape is defined in a manner in which the surface area of the inner structure 140 which is in physical contact with the piezoelectric units 110, 112, 115, 118 when in resting position is less than 5 percent of the total surface area of the inner structure 140. In some cases, the inner structure 140's shape is defined in a manner in which the surface area of the inner structure 140 which is in physical contact with the piezoelectric units 110, 112, 115, 118 when in resting position is less than 3 percent of the total surface area of the inner structure 140.

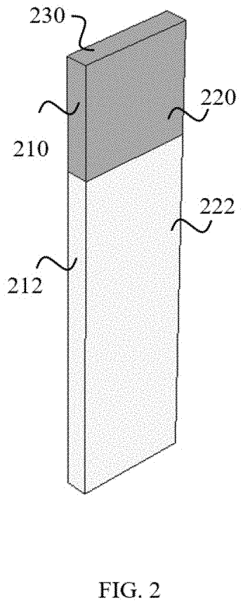

FIG. 2 shows a single cantilever-shaped piezoelectric unit. The piezoelectric unit is configured to be fixed at its base to a wall of the outer structure. The distal section is the area of the piezoelectric unit located away from the wall of the outer structure. The permanent magnet may have a wide surface 220 and a narrow surface 210, depending on the shape of the piezoelectric unit.

The piezoelectric unit may also be defined by a top surface 230, which is the farthest point from the inner wall of the outer structure to which piezoelectric unit is coupled. The piezoelectric unit also includes a non-magnetic part, defined by a wide surface 222 and a narrow surface 212.

The frame of the inner structure may be of metal consistency in order to maximize the mass of the inner structure. The larger the mass of the inner structure, the more energy can be harvested from the device.

The six cantilever-shaped piezoelectric units may be arranged in three pairs. Each pair of piezoelectric units may then be fixed to one of three walls of the outer structure. The cantilever-shaped piezoelectric units within a pair are positioned parallel to each other. The distance between the two cantilever-shaped piezoelectric units within a pair is greater than the length of a longitudinal axis of the inner structure cube and allows for sufficient space for motion of the inner structure.

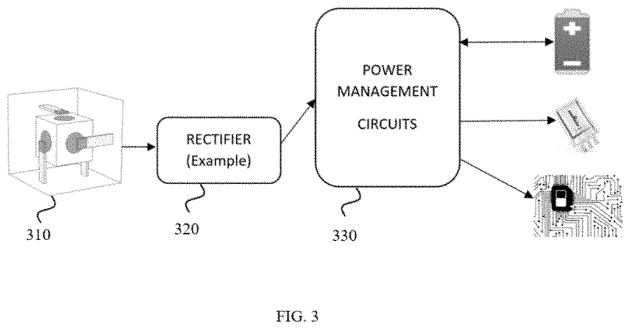

FIG. 3 shows an energy harvesting system diagram, according to exemplary embodiments of the invention. The diagram shows options of a power management circuit 330, such as a battery, a super capacitor or an electronic circuit to the device for harvesting energy 310. The system may also include a rectifier 320, coupled to both the device for harvesting energy 310 and to the power management circuit 330. The electrical circuit may be part of frame, and/or the inner structure or attached to the frame or even connected with wires from the outside the outer structure. In some cases, one part of the electrical circuit may be placed inside the outer structure and another part of the electrical circuit may be placed outside the outer structure.

Although the invention has been described in conjunction with specific embodiments thereof, it is evident that many alternatives, modifications, and variations will be apparent to those skilled in the art. Accordingly, it is intended to embrace all such alternatives, modifications and variations that fall within the spirit and broad scope of the invention.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the invention. To the extent that section headings are used, they should not be construed as necessarily limiting.

What is claimed is:

1. A device for harvesting motion energy, the device comprising:
an outer structure;
a plurality of piezoelectric units comprising a permanent source of electromagnetic field (magnet or electret) attached to a piezoelectric material;
wherein each of said piezoelectric units is fixed, at least in part, to said outer structure;
an inner structure located inside the outer structure;
wherein said inner structure is configured to be free to move within said outer structure due to changes in acceleration of motion of the outer structure;
an electric circuit configured to store or provide electric energy supplied by said piezoelectric units due to strain caused by relative motion between said outer structure and said inner structure.

2. The device of claim 1, wherein the piezoelectric units are in the form of cantilevers fixed at one end to the outer structure.

3. The device of claim 2, wherein comprising six piezoelectric units, wherein the outer structure comprising at least three perpendicular walls.

4. The device of claim 1, wherein the inner structure is a polytope having multiple sides.

5. The device of claim 1, wherein the inner structure is a ball

6. The device of claim 1, wherein the inner structure is an ellipsoid.

7. The device of claim 1, wherein the inner structure is a paraboloid.

8. The device of claim 1, wherein the inner structure is a hyperboloid.

9. The apparatus of claim 1, wherein the electric circuit comprises means to store the electric energy.

10. The device of claim 1, wherein the device is a wearable device.

11. The device of claim 1, wherein the plurality of piezoelectric arms deforms in response to movement of the inner structure relative to the plurality of piezoelectric arms.

12. The device of claim 1, wherein the inner structure is made of metallic material.
